(19) United States
(12) Patent Application Publication
(10) Pub. No.: US 2025/0210603 A1
(43) Pub. Date: Jun. 26, 2025

(54) Display Device

(71) Applicant: LG Display Co., Ltd., Seoul (KR)

(72) Inventors: Yanghwan Kim, Seoul (KR); HeeJin Im, Goyang-si (KR)

(21) Appl. No.: 18/775,642

(22) Filed: Jul. 17, 2024

(30) Foreign Application Priority Data
Dec. 26, 2023 (KR) 10-2023-0191280

(51) Int. Cl. H01L 25/16; H01L 25/075; H01L 33/58

(52) U.S. Cl. CPC H01L 25/167; H10H 20/855; H01L 25/0753; H10H 20/882

(57) ABSTRACT

A display device presented herein comprises a substrate with a plurality of subpixels on the substrate, a plurality of light-emitting elements on the substrate in each of the plurality of subpixels, a plurality of bonding layers between the plurality of light-emitting elements and the substrate, the plurality of bonding layers overlapping the plurality of light-emitting elements, and a scattering layer on a same plane as the plurality of bonding layers, the scattering layer surrounding the plurality of bonding layers. The display device presented herein features increased efficiency in extracting light, enhanced brightness uniformity depending on the viewing angle, and suppressed image quality degradation.

### CROSS-REFERENCE TO RELATED APPLICATION

This application claims the priority from Republic of Korea Patent Application No. 10-2023-0191280 filed on Dec. 26, 2023, which is hereby incorporated by reference in its entirety.

### BACKGROUND

### Field

The present disclosure relates to a display device, and more particularly, to a display device using a light-emitting diode (LED).

### Description of Related Art

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### SUMMARY

An object to be achieved by the present disclosure is to provide a display device capable of operating with low power consumption by virtue of improved light extraction efficiency.

Another object to be achieved by the present disclosure is to provide a display device with improved brightness uniformity depending on a viewing angle.

Still another object to be achieved by the present disclosure is to provide a display device with no image quality degradation despite the use of a scattering layer.

Technical problems of the present disclosure are not limited to the aforementioned technical problems, and other technical problems, which are not mentioned above, may be clearly understood by those skilled in the art from the following descriptions.

The display device according to the present disclosure, comprises a substrate with a plurality of subpixels on the substrate, a plurality of light-emitting elements on the substrate in each of the plurality of subpixels, a plurality of bonding layers between the plurality of light-emitting elements and the substrate, the plurality of bonding layers overlapping the plurality of light-emitting elements, and a scattering layer on a same plane as the plurality of bonding layers, the scattering layer surrounding the plurality of bonding layers. The display device features increased efficiency in extracting light, enhanced brightness uniformity depending on the viewing angle, and suppressed image quality degradation.

Other detailed matters of embodiments of the present disclosure are included in the detailed description and the drawings.

According to the present disclosure, the efficiency in extracting light from the light-emitting element may be improved, which may allow the display device to operate with low power consumption.

According to the present disclosure, it is possible to improve brightness uniformity depending on the viewing angle of the display device.

According to the present disclosure, the scattering layer may be used to improve the light extraction efficiency and brightness uniformity and suppress the image quality degradation.

The effects according to the present disclosure are not limited to the above-mentioned effects, and more various effects are included in the present disclosure.

### BRIEF DESCRIPTION OF DRAWINGS

The above and other embodiments, features and other advantages of the present disclosure will be more clearly understood from the following detailed description taken in conjunction with the accompanying drawings, in which:

FIG. 1 is a schematic configuration view of a display device according to one or more embodiments of the present disclosure;

FIG. 2A is a partial cross-sectional view of the display device according to one or more embodiments of the present disclosure;

FIG. 2B is a perspective view of a tiling display device according to one or more embodiments of the present disclosure;

FIG. 3 is a schematic enlarged top plan view of a display area of the display device according to one or more embodiments of the present disclosure;

FIG. 4 is a cross-sectional view of a first subpixel of the display device according to one or more embodiments of the present disclosure;

FIG. 5 is a cross-sectional view of a first subpixel of a display device according to one or more embodiments of the present disclosure; and

FIGS. 6A to 6F are graphs illustrating brightness distributions depending on viewing angles of the display device according to one or more embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to embodiments of the present disclosure will be described in detail with reference to accompanying drawings.

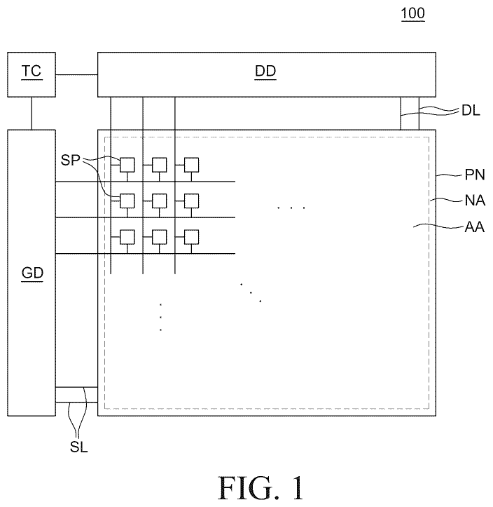

FIG. 1 is a schematic configuration view of a display device according to one or more embodiments of the present disclosure.

For convenience of description, FIG. 1 illustrates only a display panel PN, a gate drive part GD, a data drive part DD, and a timing controller TC among various constituent elements of a display device 100.

With reference to FIG. 1, the display device 100 may include the display panel PN including a plurality of subpixels SP, the gate drive part GD configured to supply various types of signals to the display panel PN, and the timing controller TC configured to control the data drive part DD, the gate drive part GD, and the data drive part DD.

The gate drive part GD supplies a plurality of scan signals to a plurality of scan lines SL in response to a plurality of gate control signals provided from the timing controller TC. FIG. 1 illustrates that the single gate drive part GD is disposed to be spaced apart from one side of the display panel PN. However, the number and arrangement of the gate drive part GD are not limited thereto.

The data drive part DD converts image data, which are inputted from the timing controller TC, into a data voltage by using a reference gamma voltage in response to a plurality of data control signals provided from the timing controller TC. The data drive part DD may supply the converted data voltage to a plurality of data lines DL.

The timing controller TC aligns image data, which are inputted from the outside, and supplies the image data to the data drive part DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and may include the plurality of subpixels SP. In the display panel PN, the plurality of scan lines SL and the plurality of data lines DL may intersect one another, and each of the plurality of subpixels SP may be connected to the scan line SL and the data line DL. In addition, the plurality of subpixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include the plurality of subpixels SP constituting a plurality of pixels PX, and a circuit configured to operate the plurality of subpixels SP. The plurality of subpixels SP is minimum units that constitute the display area AA. The n subpixels SP may constitute a single pixel PX. A light-emitting element 120, a thin-film transistor for operating the light-emitting element 120, and the like may be disposed in each of the plurality of subpixels SP. The plurality of light emitting elements 120 may be differently defined depending on the type of display panel PN. For example, in case that the display panel PN is an inorganic light-emitting display panel PN, the light-emitting element 120 may be a light-emitting diode (LED) or a micro light-emitting diode (micro-LED).

A plurality of signal lines for transmitting various types of signals to the plurality of subpixels SP may be disposed in the display area AA. For example, the plurality of signal lines may include the plurality of data lines DL for supplying data voltages to the plurality of subpixels SP, and the plurality of scan lines SL for supplying gate voltages to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP. In addition, a low-potential power line, a high-potential power line, and the like may be further disposed in the display area AA. However, the present disclosure is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate drivers IC and data drivers IC.

Meanwhile, the non-display area NA may be positioned on a rear surface of the display panel PN, i.e., a surface on which the subpixel SP is not present. Alternatively, the non-display area NA may be excluded. However, the present disclosure is not limited to the configuration illustrated in the drawings.

Meanwhile, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of subpixels SP by a gate-in-active area (GIA) method in the display area AA. For example, the data drive part DD and the timing controller TC may be formed on a separate flexible film and a printed circuit board 110 and electrically connected to the display panel PN by a method of bonding the flexible film and the printed circuit board 110 to a pad electrode formed in the non-display area NA of the display panel PN. In case that the gate drive part GD is mounted by the GIP method and the data drive part DD and the timing controller TC transmit signals to the display panel PN through the pad electrode in the non-display area NA, it is necessary to ensure an area of the non-display area NA in order to dispose the gate drive part GD and the pad electrode, which may increase a bezel.

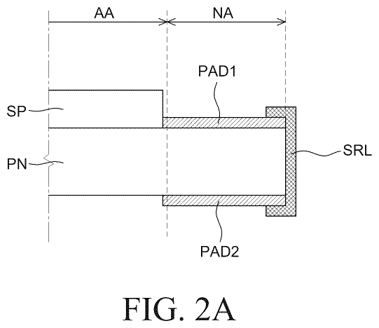

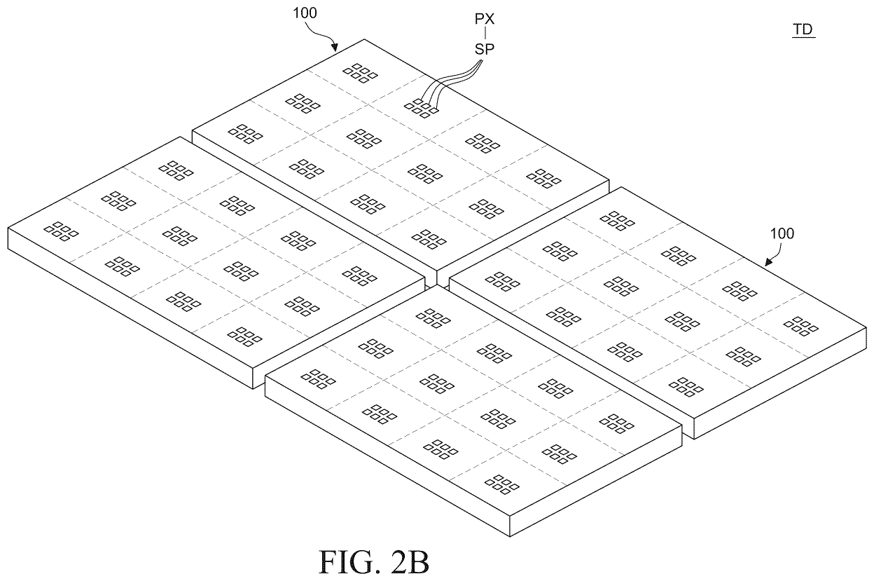

Alternatively, in case that the gate drive part GD is mounted in the display area AA by the GIA method and a side line SRL, which connects a signal line on a front surface of the display panel PN to the pad electrode on the rear surface of the display panel PN, is formed to bond the flexible film and the printed circuit board 110 to the rear surface of the display panel PN, it is possible to minimize or at least reduce the non-display area NA on the front surface of the display panel PN. That is, in case that the gate drive part GD, the data drive part DD, and the timing controller TC are connected to the display panel PN by the above-mentioned method, a zero bezel in which the bezel is not substantially present may be implemented. A more detailed description will be described with reference to FIGS. 2A and 2B.

FIG. 2A is a partial cross-sectional view of the display device according to one or more embodiments of the present disclosure. FIG. 2B is a perspective view of a tiling display device according to one or more embodiments of the present disclosure.

A plurality of pad electrodes for transmitting various types of signals to the plurality of subpixels SP may be disposed in the non-display area NA of the display panel PN. For example, a first pad electrode PAD1 configured to transmit signals to the plurality of subpixels SP may be disposed in the non-display area NA on the front surface of the display panel PN. A second pad electrode PAD2 electrically connected to drive components such as the flexible film and the printed circuit board 110 may be disposed in the non-display area NA on the rear surface of the display panel PN.

In this case, various types of signal lines, e.g., the scan line SL, the data line DL, or the like connected to the plurality of subpixels SP may extend from the display area AA to the non-display area NA and be electrically connected to the first pad electrode PAD1.

Further, the side line SRL may be disposed along a side surface of the display panel PN. The side line SRL may electrically connect the first pad electrode PAD1 on the front surface of the display panel PN and the second pad electrode PAD2 on the rear surface of the display panel PN. Therefore, the signals received from the drive components on the rear surface of the display panel PN may be transmitted to the plurality of subpixels SP through the second pad electrode PAD2, the side line SRL, and the first pad electrode PAD1. Therefore, a signal transmission route is defined from the front surface to the side surface and the rear surface of the display panel PN, which may minimize or at least reduce an area of the non-display area NA of the display panel PN.

Further, with reference to FIG. 2B, a tiling display device TD having a large screen may be implemented by connecting a plurality of display devices 100. In this case, as illustrated in FIG. 2A, in case that the tiling display device TD is implemented by using the display device 100 with the minimized or at least reduced bezel, a seam area in which no image is displayed between the display devices 100 may be minimized or at least reduced, thereby improving display quality.

For example, the plurality of subpixels SP may constitute a single pixel PX. An interval D1 between an outermost peripheral pixel PX of one display device 100 and an outermost peripheral pixel PX of another display device 100 adjacent to one display device 100 may be implemented to be equal to the interval D1 between the pixels PX in one display device 100. Therefore, the seam area may be minimized or at least reduced as a constant interval of the pixels PX is implemented between the display device 100 and the display device 100.

However, as illustrated in FIG. 2A and FIG. 2B, the display device 100 according to one or more embodiments of the present disclosure may be a general display device in which the bezel is present. However, the present disclosure is not limited thereto.

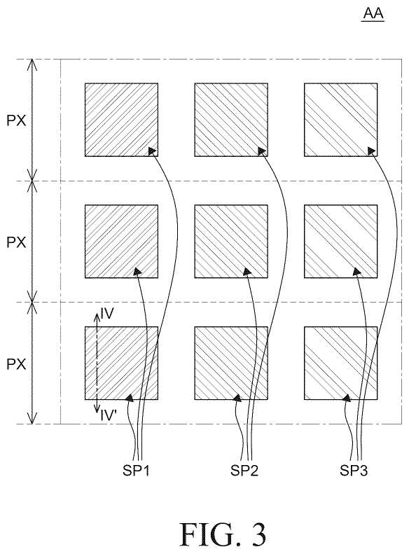

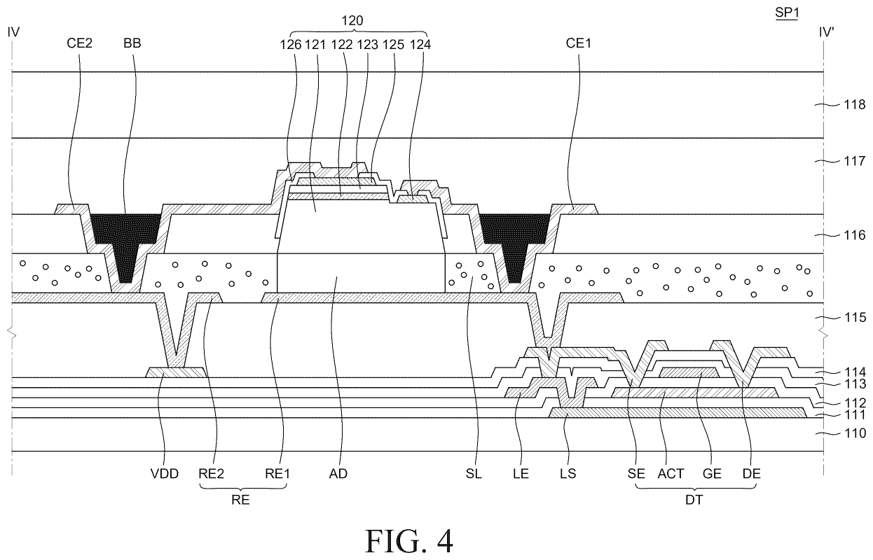

FIG. 3 is a schematic enlarged top plan view of the display area of the display device according to one or more embodiments of the present disclosure. FIG. 4 is a cross-sectional view of a first subpixel of the display device according to one or more embodiments of the present disclosure.

First, with reference to FIG. 3, the display panel PN includes the plurality of pixels PX each having the plurality of subpixels SP. The plurality of subpixels SP may each include the light-emitting element 120 and the pixel circuit and independently emit light. For example, a first subpixel SP1 may be a red subpixel, a second subpixel SP2 may be a green subpixel, and a third subpixel SP3 may be a blue subpixel. However, the present disclosure is not limited thereto.

With reference to FIG. 4, the display device 100 according to one or more embodiments of the present disclosure may include a substrate 110, a buffer layer 111, a gate insulation layer 112, a first interlayer insulation layer 113, a second interlayer insulation layer 114, a first planarization layer 115, a bonding layer AD, a scattering layer SL, a second planarization layer 116, a third planarization layer 117, a protective layer 118, a black matrix BB, a driving transistor DT, a power line VDD, the light-emitting element 120, a plurality of reflective electrodes RE, a plurality of first connection electrodes CE1, a second connection electrode CE2, a light-blocking layer LS, and an auxiliary electrode LE.

First, the substrate 110 is a component for supporting various constituent elements included in the display device 100 and may be made of an insulating material. For example, the substrate 110 may be made of glass, resin, or the like. In addition, the substrate 110 may include plastic such as polymer and may be made of a material having flexibility.

The light-blocking layer LS may be disposed on each of the plurality of subpixels SP on the substrate 110. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing or at least reducing a leakage current.

The buffer layer 111 may be disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto.

The driving transistor DT may be disposed on the buffer layer 111. The driving transistor DT may include the active layer ACT, a gate electrode GE, a source electrode SE, and a drain electrode DE.

The active layer ACT may be disposed on the buffer layer 111. The active layer ACT may be made of a semiconductor material such as an oxide semiconductor, amorphous silicon, or polysilicon. However, the present disclosure is not limited thereto.

The gate insulation layer 112 may be disposed on the active layer ACT. The gate insulation layer 112 is an insulation layer for insulating the active layer ACT and the gate electrode GE. The gate insulation layer 112 may be configured as a single layer or multilayer made of silicon oxide (SiOx) or silicon nitride (SiNx). However, the present disclosure is not limited thereto.

The gate electrode GE may be disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first interlayer insulation layer 113 and the second interlayer insulation layer 114 may be disposed on the gate electrode GE. Contact holes, through which the source electrode SE and the drain electrode DE are connected to the active layer ACT, may be formed in the first interlayer insulation layer 113 and the second interlayer insulation layer 114. The first interlayer insulation layer 113 and the second interlayer insulation layer 114 may be insulation layers for protecting components disposed below the first interlayer insulation layer 113 and components disposed below the second interlayer insulation layer 114 and each configured as a single layer or multilayer made of silicon oxide (SiOx) or silicon nitride (SiNx). However, the present disclosure is not limited thereto.

The source electrode SE and the drain electrode DE, which are electrically connected to the active layer ACT, may be disposed on the second interlayer insulation layer 114. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, in the present disclosure, the configuration has been described in which the first interlayer insulation layer 113 and the second interlayer insulation layer 114, i.e., the plurality of insulation layers is disposed between the gate electrode GE, the source electrode SE, and the drain electrode DE. However, only a single insulation layer may be disposed between the gate electrode GE, the source electrode SE, and the drain electrode DE. However, the present disclosure is not limited thereto.

Further, as illustrated in the drawings, in case that the plurality of insulation layers, such as the first interlayer insulation layer 113 and the second interlayer insulation layer 114, is disposed between the gate electrode GE, the source electrode SE, and the drain electrode DE, an electrode may be additionally formed between the first interlayer insulation layer 113 and the second interlayer insulation layer 114. The additionally formed electrode may define a capacitor together with other components disposed on the lower portion of the first interlayer insulation layer 113 or the upper portion of the second interlayer insulation layer 114.

The auxiliary electrode LE may be disposed on the gate insulation layer 112. The auxiliary electrode LE is an electrode that electrically connects the light-blocking layer LS, disposed below the buffer layer 111, to any one of the source electrode SE and the drain electrode DE on the second interlayer insulation layer 114. For example, the light-blocking layer LS may be electrically connected to any one of the source electrode SE or the drain electrode DE through the auxiliary electrode LE so as not to be operated as a floating gate, thereby minimizing or at least reducing a change in threshold voltage of the driving transistor DT caused by the floating light-blocking layer LS. FIG. 4 illustrates that the light-blocking layer LS is connected to the source electrode SE. However, the light-blocking layer LS may be connected to the drain electrode DE. However, the present disclosure is not limited thereto.

The power line VDD may be disposed on the second interlayer insulation layer 114. The power line VDD may be electrically connected to the light-emitting element 120 together with the driving transistor DT and allow the light-emitting element 120 to emit light. The power line VDD may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first planarization layer 115 may be disposed on the driving transistor DT and the power line VDD. The first planarization layer 115 may planarize the upper portion of the substrate 110 on which the driving transistor DT is disposed. The first planarization layer 115 may be configured as a single layer or multilayer and made of a photoresist or an acrylic-based organic material, for example. However, the present disclosure is not limited thereto.

The plurality of reflective electrodes RE, spaced apart from one another, may be disposed on the first planarization layer 115. The plurality of reflective electrodes RE may serve to electrically connect the light-emitting element 120 to the power line VDD and the driving transistor DT and serve as a reflective plate that reflects light, emitted from the light-emitting element 120, to an upper portion of the light-emitting element 120. The plurality of reflective electrodes RE may each be made of an electrically conductive material having excellent reflection performance and reflect the light, emitted from the light-emitting element 120, toward the upper portion of the light-emitting element 120.

The plurality of reflective electrodes RE may include a first reflective electrode RE1 and a second reflective electrode RE2. The first reflective electrode RE1 may electrically connect the driving transistor DT and the light-emitting element 120. The first reflective electrode RE1 may be connected to the source electrode SE or the drain electrode DE of the driving transistor DT through a contact hole formed in the first planarization layer 115. Further, the first reflective electrode RE1 may be electrically connected to a first electrode 124 and a first semiconductor layer 121 of the light-emitting element 120 through the first connection electrode CE1 to be described below.

The second reflective electrode RE2 may electrically connect the power line VDD and the light-emitting element 120. The second reflective electrode RE2 may be connected to the power line VDD through the contact hole, formed in the first planarization layer 115, and electrically connected to a second electrode 125 and a second semiconductor layer 123 of the light-emitting element 120 through the second connection electrode CE2 to be described below.

The bonding layer AD and the scattering layer SL are disposed on the first planarization layer 115 and the plurality of reflective electrodes RE.

The bonding layer AD may be disposed to overlap the plurality of light-emitting elements to be described below and fix the light-emitting elements disposed on the bonding layer AD. For example, the bonding layer AD may be made of any one material selected from adhesive polymer, epoxy resist, UV resin, a polyimide-based material, an acrylate-based material, a urethane-based material, and polydimethylsiloxane (PDMS). However, the present disclosure is not limited thereto.

The plurality of bonding layers AD may completely overlap the plurality of light-emitting elements, respectively. In addition, an area of a top surface of each of the plurality of bonding layers may be equal to an area of a bottom surface of each of the plurality of light-emitting elements respectively overlapping the plurality of bonding layers.

The scattering layer SL is disposed on the same plane as the bonding layer AD and surrounds the plurality of bonding layers AD.

The scattering layer may include scattering particles, and a bonding material in which the scattering particles are dispersed.

The scattering particles may scatter the light, emitted from the light-emitting element, in a visual field direction. Titanium oxide (TiO₂), zirconium oxide (ZrO₂), or the like having nano sizes may be used for the scattering particles. However, the present disclosure is not limited thereto.

The bonding material may be made of the same material as the plurality of bonding layers. For example, the bonding material may be selected as any one of adhesive polymer, epoxy resist, UV resin, a polyimide-based material, an acrylate-based material, a urethane-based material, and polydimethylsiloxane (PDMS). However, the present disclosure is not limited thereto.

Meanwhile, FIG. 4 illustrates that the bonding layer AD and the scattering layer SL are separate components disposed on the same layer. However, the present disclosure is not limited thereto. That is, the bonding layer AD and the scattering layer SL may be separate components having an interface therebetween. The bonding layer and the scattering layer may be formed as a single layer and formed in a shape in which the scattering particles are dispersed only in a portion corresponding to the scattering layer.

The light-emitting element 120 may include the first semiconductor layer 121, a light-emitting layer 122, the second semiconductor layer 123, the first electrode 124, the second electrode 125, and an encapsulation film 126.

The first semiconductor layer 121 may be disposed on the bonding layer AD, and the second semiconductor layer 123 may be disposed on the first semiconductor layer 121. The first semiconductor layer 121 and the second semiconductor layer 123 may each be a layer formed by doping a particular material with n-type and p-type impurities. For example, the first semiconductor layer 121 and the second semiconductor layer 123 may each be a layer formed by doping a material, such as gallium nitride (GaN), indium aluminum phosphide (InAlP), or gallium arsenic (GaAs) with n-type and p-type impurities. Further, the p-type impurity may be magnesium, zinc (Zn), beryllium (Be), or the like. The n-type impurity may be silicon (Si), germanium, tin (Sn), or the like. However, the present disclosure is not limited thereto.

The light-emitting layer 122 may be disposed between the first semiconductor layer 121 and the second semiconductor layer 123. The light-emitting layer 122 may emit light by receiving positive holes and electrons from the first semiconductor layer 121 and the second semiconductor layer 123. The light-emitting layer 122 may be configured as a single layer or a multi-quantum well (MQW) structure. For example, the light-emitting layer 122 may be made of indium gallium nitride (InGaN), gallium nitride (GaN), or the like. However, the present disclosure is not limited thereto.

The first electrode 124 may be disposed on the first semiconductor layer 121. The first electrode 124 is an electrode that electrically connects the driving transistor DT and the first semiconductor layer 121. The first electrode 124 may be disposed on a top surface of the first semiconductor layer 121 exposed from the light-emitting layer 122 and the second semiconductor layer 123. The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 may be disposed on the second semiconductor layer 123. The second electrode 125 may be disposed on a top surface of the second semiconductor layer 123. The second electrode 125 is an electrode for electrically connecting the power line VDD and the second semiconductor layer 123. The second electrode 125 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Next, the encapsulation film 126 may be disposed to surround the first semiconductor layer 121, the light-emitting layer 122, the second semiconductor layer 123, the first electrode 124, and the second electrode 125. The encapsulation film 126 may be made of an insulating material and protect the first semiconductor layer 121, the light-emitting layer 122, and the second semiconductor layer 123. Further, a contact hole, through which the first electrode 124 and the second electrode 125 are exposed, may be formed in the encapsulation film 126, such that the first connection electrode CE1, the second connection electrode CE2, the first electrode 124, and the second electrode 125 may be electrically connected.

Meanwhile, a part of a side surface of the first semiconductor layer 121 may be exposed from the encapsulation film 126. The light-emitting element 120 manufactured on a wafer may be separated from the wafer and transferred to the display panel PN. However, a part of the encapsulation film 126 may be torn during a process of separating the light-emitting element 120 from the wafer. For example, a part of the encapsulation film 126 adjacent to a lower edge of the first semiconductor layer 121 of the light-emitting element 120 may be torn during the process of separating the light-emitting element 120 from the wafer, such that a lower portion of the side surface of the first semiconductor layer 121 may be exposed to the outside. However, even though the lower portion of the light-emitting element 120 is exposed from the encapsulation film 126, the first connection electrode CE1 and the second connection electrode CE2 are formed after the second planarization layer 116, which covers the side surface of the first semiconductor layer 121, is formed, thereby reducing a short circuit defect.

The second planarization layer 116 may be disposed on at least a part of the bonding layer AD or the scattering layer SL. The second planarization layer 116 may at least partially overlap the side surfaces of the plurality of light-emitting elements 120 and fix and protect the plurality of light-emitting elements 120. The second planarization layer 116 may be configured as a single layer or multilayer and made of a photoresist or an acrylic-based organic material, for example. However, the present disclosure is not limited thereto.

The first connection electrode CE1 and the second connection electrode CE2 may be disposed on the second planarization layer 116 and the light-emitting element 120.

The first connection electrode CE1 may be an electrode that electrically connects the light-emitting element 120 and the driving transistor DT. The first connection electrode CE1 may be connected to the first reflective electrode RE1 through contact holes formed in the second planarization layer 116 and the bonding layer AD. Therefore, the first connection electrode CE1 may be electrically connected to any one of the source electrode SE and the drain electrode DE of the driving transistor DT through the first reflective electrode RE1. Further, the first connection electrode CE1 may be connected to the first electrode 124 of the light-emitting element 120 while covering the light-emitting element 120. Therefore, the first connection electrode CE1 may electrically connect the driving transistor DT and the first electrode 124 and the first semiconductor layer 121 of each of the plurality of light-emitting elements 120.

The second connection electrode CE2 may be an electrode that electrically connects the light-emitting element 120 and the power line VDD. The second connection electrode CE2 may be connected to the second reflective electrode RE2 through contact holes formed in the second planarization layer 116 and the bonding layer AD. Therefore, the second connection electrode CE2 may be electrically connected to the power line VDD through the second reflective electrode RE2. Further, the second connection electrode CE2 may be connected to the second electrode 125 of the light-emitting element 120 while covering the light-emitting element 120. Therefore, the second connection electrode CE2 may electrically connect the power line VDD and the second electrode 125 and the second semiconductor layer 123 of each of the plurality of light-emitting elements 120.

The bank BB may be disposed on the first connection electrode CE1 and the second connection electrode CE2. The bank BB may be disposed to be spaced apart from the light-emitting element 120 at a predetermined interval. For example, the bank BB may be spaced apart from the light-emitting element 120 at a predetermined interval and partially cover the first connection electrode CE1 and the second connection electrode CE2 formed in the contact holes of the scattering layer SL and the second planarization layer 116. The bank BB may be made of an opaque material, for example, black resin to reduce a color mixture between the plurality of subpixels SP. However, the present disclosure is not limited thereto.

The third planarization layer 117 may be disposed on the first connection electrode CE1, the second connection electrode CE2, the light-emitting element 120, and the bank BB. The third planarization layer 117 may cover the light-emitting element 120 to protect the light-emitting element 120. The third planarization layer 117 may be configured as a single layer or multilayer and made of a photoresist or an acrylic-based organic material, for example. However, the present disclosure is not limited thereto. The planarization layer may be configured as a single layer. However, the present disclosure is not limited thereto.

A fourth planarization layer 118 may be disposed on the third planarization layer 117. The fourth planarization layer 118 may cover the third planarization layer 117 and protect the components disposed below the fourth planarization layer 118. The fourth planarization layer 118 may be configured as a single layer or multilayer and made of a photoresist or an acrylic-based organic material, for example. However, the present disclosure is not limited thereto. Meanwhile, in the present disclosure, the configuration has been described in which the second planarization layer 116, the third planarization layer 117, and the fourth planarization layer 118 are disposed. However, the planarization layer may be configured as a single layer. However, the present disclosure is not limited thereto.

The protective layer 118 may be further disposed on the fourth planarization layer 118. The protective layer 118 may be a layer for protecting components disposed below the protective layer 118 and configured as a single layer or multilayer made of light transmissive epoxy, silicon oxide (SiOx), or silicon nitride (SiNx). However, the present disclosure is not limited thereto.

In the case of an organic light-emitting display device, there is a problem in that an organic light-emitting element made of an organic material is very vulnerable to moisture or oxygen. Therefore, there is a limitation in reducing a size of a bezel area when an encapsulation part for the organic light-emitting element is disposed. As an alternative, an LED, made of an inorganic material instead of an organic material, may be used as a light-emitting element, such that images with excellent luminous efficiency and high brightness may be displayed. For example, a micro-LED may be used when a size of the LED is 100 μm or less. As described above, the display device using the small-sized LED may display images with excellent luminous efficiency and high brightness. However, because the small-scale LED has the light-emitting element with a very small size, the amount of light emitted in the direction of the side surface is larger than the amount of light emitted in the direction of the front surface in comparison with the LED with a relatively large size. For this reason, the brightness uniformity deteriorates in the direction of the front surface and the direction of the side surface.

Therefore, in the display device 100 according to one or more embodiments of the present disclosure, the scattering layer SL including the scattering particles is disposed in a lower area that does not overlap the light-emitting element 120. Therefore, the scattering layer may change the path of the light by scattering the light that is not outputted to the outside because the light emitted from the light-emitting element 120 is totally reflected in the pixel. As described above, the change in the path of the light may allow the light, trapped in the pixel, to be outputted to the outside, which may improve the light extraction efficiency and enable the display device to operate with low power consumption.

Meanwhile, the amount of light propagating toward the lower side of the light-emitting element without a viewing angle is larger than the amount of light propagating toward the lower side of the light-emitting element and toward the side surface while having a viewing angle. In addition, the light propagating without a viewing angle is reflected by the first reflective electrode, which may be disposed below the light-emitting element, and reflected to the front surface in the visual field direction. Therefore, in case that the scattering layer is disposed in the lower area that overlaps the light-emitting element, the scattering layer changes the path of the light by scattering the light propagating to the lower side of the light-emitting element without a viewing angle, such that the amount of light emitted to the front surface (viewing angle of) 0° in the visual field direction may decrease, and the amount of light emitted in the direction of the side surface having a viewing angle based on the front surface in the visual field direction may rather increase. As a result, brightness non-uniformity between the front brightness and the side brightness may become severe in the visual field direction.

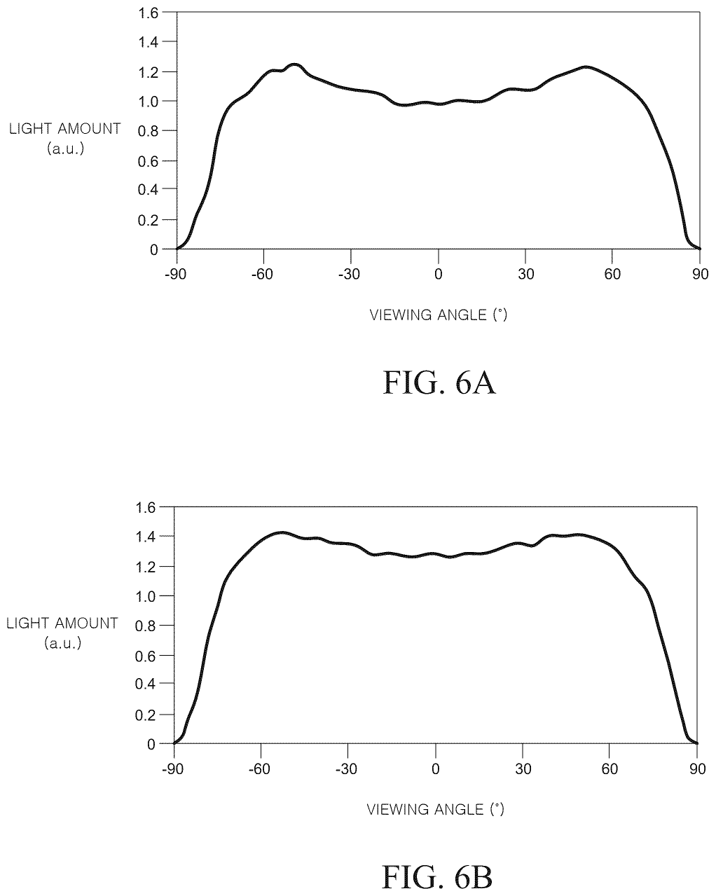

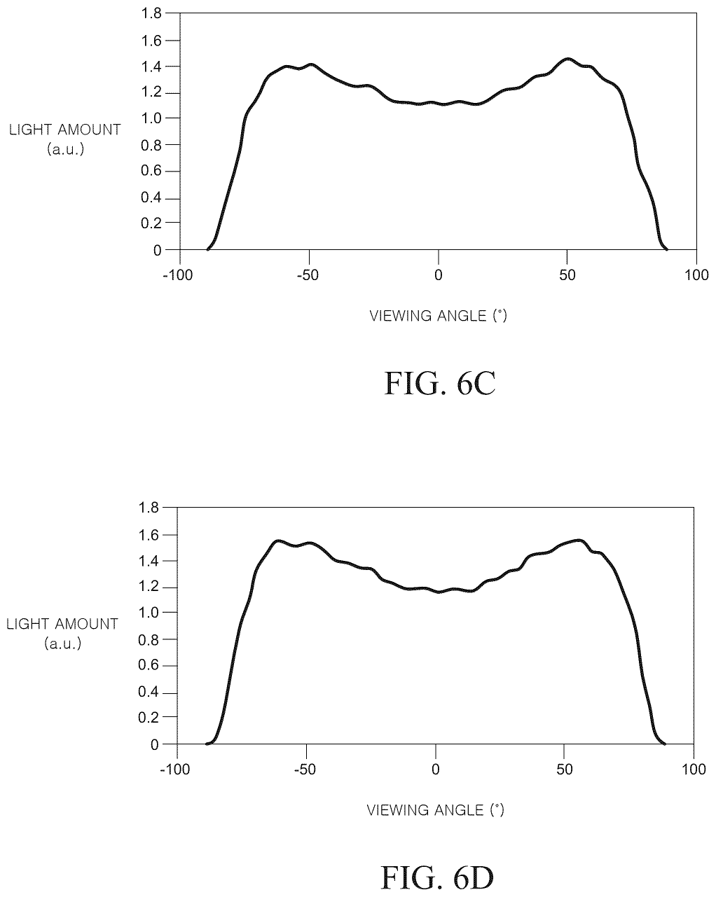

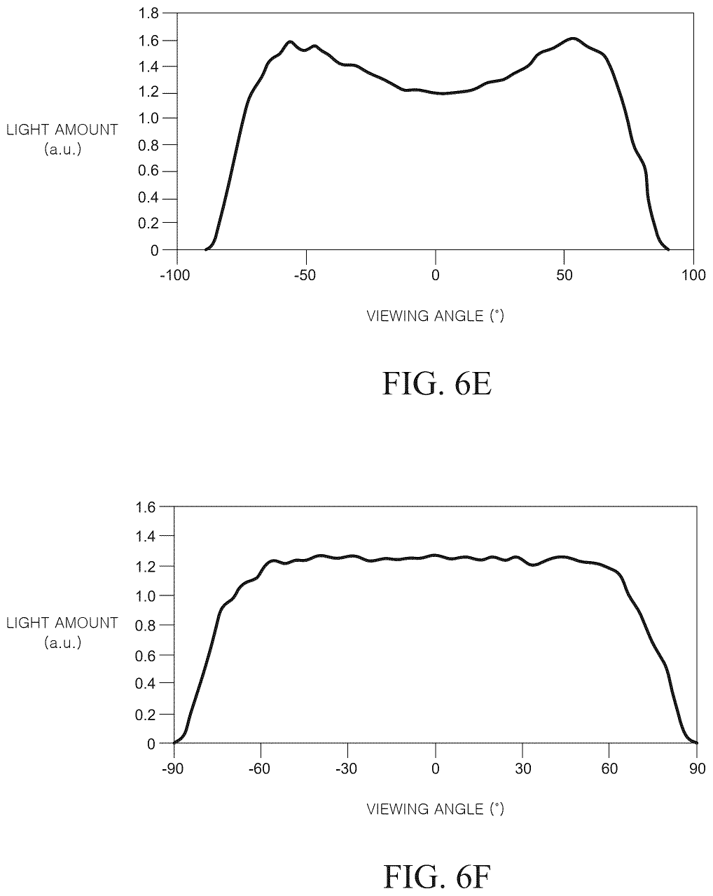

Therefore, in the display device 100 according to one or more embodiments of the present disclosure, the scattering layer SL is not disposed in the lower area that overlaps the light-emitting element 120. Therefore, the light, which propagates to the lower side of the light-emitting element 120 without a viewing angle, is not scattered, which may reduce a loss of light emitted to the front surface in the visual field direction. In addition, the light, emitted from the light-emitting element 120 in the direction of the lower side surface of the light-emitting element 120, may be scattered, such that a path of a part of the scattered light may be changed to the direction of the front surface in the visual field direction. That is, as illustrated in FIG. 6F, the amount of light emitted to the front surface (viewing angle of) 0° in the visual field direction increases, such that the front brightness may be improved. Further, the amount of light emitted to the side surface having the viewing angle in the visual field direction decreases, such that the brightness uniformity between the front brightness and the side brightness in the visual field direction may be improved.

In addition, in the display device 100 according to one or more embodiments of the present disclosure, the scattering layer SL is not provided above the light-emitting element 120 and in the area overlapping the lower side of the light-emitting element 120, which may suppress the occurrence of image quality degradation caused by the scattering layer SL.

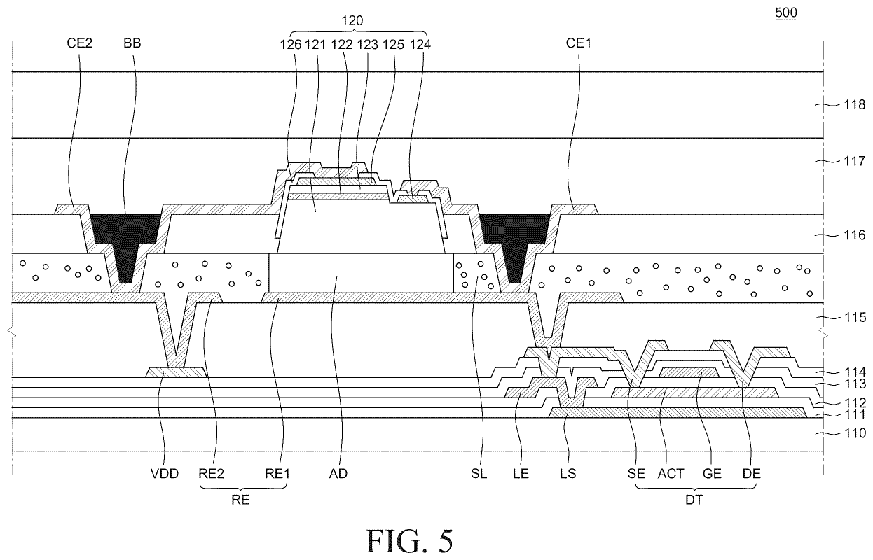

FIG. 5 is a cross-sectional view of a first subpixel of a display device 500 according to one or more embodiments of the present disclosure. The display device 500 in FIG. 5 is substantially identical in configuration to the display device 100 in FIGS. 1 to 4, except for the arrangement of the bonding layer AD and the scattering layer SL. Therefore, a repeated description will be omitted.

With reference to FIG. 5, in the display device 500 according to one or more embodiments of the present disclosure, the plurality of scattering layers SL may be disposed outside the plurality of light-emitting elements 120.

In addition, an area of a top surface of each of the plurality of bonding layers AD may be larger than an area of a bottom surface of each of the plurality of light-emitting elements 120 respectively overlapping the plurality of bonding layers AD. In this case, the top surface of the bonding layer AD and the bottom surface of the light-emitting element 120 may mean surfaces on which the bonding layer AD and the light-emitting element 120 adjoin each other.

Therefore, in the display device 500 according to one or more embodiments of the present disclosure, the light-emitting element 120 adopts the scattering layer SL, such that the path of the light may be changed so that the light emitted from the light-emitting element 120 may be outputted to the outside without trapped in the pixel. Therefore, it is possible to improve the light extraction efficiency of the display device 500 and enable the display device 500 to operate with low power consumption.

In addition, in the display device 500 according to one or more embodiments of the present disclosure, the scattering layer SL is not disposed in the lower area that overlaps the light-emitting element 120, which may reduce a loss of light emitted to the front surface in the visual field direction. Therefore, the amount of light emitted to the front surface in the visual field direction increases, such that the front brightness may be improved. Further, the amount of light emitted to the side surface having the viewing angle in the visual field direction decreases, such that the brightness uniformity between the front brightness and the side brightness in the visual field direction may be improved.

In addition, in the display device 500 according to one or more embodiments of the present disclosure, the scattering layer SL is not provided above the light-emitting element 120 and in the area overlapping the lower side of the light-emitting element 120, which may suppress the occurrence of image quality degradation caused by the scattering layer SL.

In addition, in the display device 500 according to one or more embodiments of the present disclosure, an end of the bonding layer AD is disposed outside the organic light-emitting element 120, such that the organic light-emitting element 120 and the scattering layer SL may not overlap even though a problem, such as transfer tolerance, occurs during a process of transferring the light-emitting element 120. Therefore, it is possible to suppress the deterioration in brightness uniformity between the front brightness and the side brightness in the visual field direction even though a problem, such as misalignment, occurs during the process of transferring the light-emitting element 120.

FIGS. 6A to 6F are graphs illustrating brightness distributions depending on viewing angles of the display device according to one or more embodiments of the present disclosure. FIG. 6A is a graph showing a brightness distribution depending on a viewing angle of a display device according to a first embodiment of the present disclosure. FIG. 6B is a graph showing a brightness distribution depending on a viewing angle of a display device according to a second embodiment of the present disclosure. FIG. 6C is a graph showing a brightness distribution depending on a viewing angle of a display device according to a third embodiment of the present disclosure. FIG. 6D is a graph showing a brightness distribution depending on a viewing angle of a display device according to a fourth embodiment of the present disclosure. FIG. 6E is a graph showing a brightness distribution depending on a viewing angle of a display device according to a fifth embodiment of the present disclosure. FIG. 6F is a graph showing brightness depending on a viewing angle of the display device 100 (hereinafter, referred to as an ‘embodiment’) according to the embodiment of the present disclosure. In FIGS. 6A to 6F, the X-axes indicate viewing angles, and the Y-axes indicate light amounts corresponding to the brightness. In this case, the light amount is represented as relative values on the basis that the front brightness, which is the light amount on the front surface (viewing angle of 0°) of the display device according to the first embodiment, is 1.0.

All the configurations of the display device according to the first embodiment are identical to those of the display device 100 according to the embodiment of the present disclosure, except that the scattering layer SL is not included. That is, in the display device according to the first embodiment, the scattering layer SL is not disposed below the light-emitting element 120, and only the bonding layer is disposed.

The display device according to the second embodiment is identical in configuration to the display device 100 according to the embodiment of the present disclosure, except that the scattering layer SL is disposed below the light-emitting element 120 even in the area that overlaps the light-emitting element 120. That is, unlike the display device 100 according to the embodiment of the present disclosure in which the scattering layer SL is not provided below the light-emitting element 120 in the area that overlaps the light-emitting element 120, the display device according to the second embodiment is configured such that the scattering layer SL is disposed below the light-emitting element 120 even in the area that overlaps the light-emitting element 120.

All the configurations of the display device according to the third embodiment are identical to those of the display device 100 according to the embodiment of the present disclosure, except that the second planarization layer 116, which surrounds the light-emitting element 120, is substituted with the scattering layer SL, the scattering layer SL is not disposed in the entire lower area of the light-emitting element 120, and only the bonding layer AD is disposed.

All the configurations of the display device according to the fourth embodiment are identical to those of the display device according to the third embodiment, except that the second planarization layer 116 is substituted with the scattering layer SL, and even the third planarization layer 117, which surrounds one side surface of the light-emitting element 120 and covers the upper side of the light-emitting element 120, is substituted with the scattering layer SL.

All the configurations of the display device according to the fifth embodiment are identical to those of the display device according to the fourth embodiment, except that the second planarization layer 116 and the third planarization layer 117 are substituted with the scattering layer SL, and even the protective layer 118 is substituted with the scattering layer SL.

The measured values of the front brightness and brightness uniformity of the display devices of the embodiment and the various embodiments illustrated in FIGS. 6A to 6F are shown in Table 1 below. In this case, the front brightness refers to the brightness at a viewing angle of 0°, and the brightness uniformity refers to the maximum brightness/front brightness at a viewing angle of −90° to 90°. Therefore, the brightness uniformity is degraded as the brightness uniformity value increases, and the brightness uniformity is improved as the brightness uniformity value decreases.

TABLE 1

| | Front Brightness (%) | Brightness Uniformity |
|---|---|---|
| Embodiment 1 | 100 | 1.25 |
| Embodiment 2 | 127 | 1.11 |
| Embodiment 3 | 110 | 1.31 |
| Embodiment 4 | 116 | 1.35 |
| Embodiment 5 | 119 | 1.35 |
| Embodiment | 127 | 1.00 |

First, with reference to FIG. 6A and Table 1, the lowest front brightness was measured when the scattering layer SL was not provided in any layer, like the display device according to the first embodiment. In addition, it can be ascertained that the brightness uniformity deteriorates in the direction of the front surface and the direction of the side surface because of the nature of the small-scale LED.

Next, with reference to FIG. 6B and Table 1, in the display device according to the second embodiment, the area of the scattering layer SL disposed below the light-emitting element 120 was increased, such that both the front brightness and the side brightness were improved, in comparison with the display device according to the first embodiment. However, when the scattering layer SL was disposed below the light-emitting element 120 even in the area that overlapped the light-emitting element 120, the front brightness was lower than the side brightness as the amount of light propagating to the front surface was decreased. For this reason, the brightness non-uniformity occurred between the front brightness and the side brightness.

Next, with reference to FIG. 6C and Table 1, in the display device according to the third embodiment, the scattering layer SL was disposed to surround one side surface of the light-emitting element 120, such that the side brightness was further improved. For this reason, the brightness non-uniformity between the front brightness and the side brightness became severe, and the front brightness was decreased, in comparison with the display device according to the second embodiment.

Next, with reference to FIG. 6D and Table 1, in the display device according to the fourth embodiment, the scattering layer SL was disposed to cover both the side surface and the upper portion of the light-emitting element 120, such that both the front brightness and the side brightness were improved. However, because the side brightness was increased more strongly, the brightness non-uniformity between the front brightness and the side brightness rather became severe.

In addition, although not shown in FIG. 6D and Table 1, in the display device according to the fourth embodiment, the scattering layer SL covered the upper portion of the light-emitting element 120, which caused the image quality degradation of the display device.

Next, with reference to FIG. 6E and Table 1, in the display device according to the fifth embodiment, the scattering layer SL was disposed to cover the side surface and the upper portion of the light-emitting element 120, such that both the front brightness and the side brightness were increased, and the brightness non-uniformity between the front brightness and the side brightness became severe.

In addition, although not shown in FIG. 6D and Table 1, in the display device according to the fifth embodiment, the scattering layer SL was formed to be thick and disposed above the light-emitting element 120, and for this reason, the image quality degradation became severe.

Next, with reference to FIG. 6F and Table 1, in the display device 100 according to the embodiment of the present disclosure, the light extraction efficiency was improved. Specifically, the front brightness was improved in comparison with the display device according to the first embodiment, the display device according to the third embodiment, the display device according to the fourth embodiment, and the display device according to the fifth embodiment, and the front brightness equal to the front brightness of the display device according to the second embodiment was measured.

In addition, in the display device 100 according to the embodiment of the present disclosure, the brightness uniformity was improved. Specifically, in the display device 100 according to the embodiment of the present disclosure, the brightness uniformity was measured as 1.0, which was lower than the brightness uniformity of the display device according to the first embodiment, the display device according to the second embodiment, the display device according to the third embodiment, the display device according to the fourth embodiment, and the display device according to the fifth embodiment.” Therefore, it was ascertained that the front brightness was measured as the same value as the maximum brightness at an omnidirectional viewing angle, and the brightness deviation depending on the viewing angle was almost eliminated. Furthermore, because the scattering layer SL was not disposed on the side surface or the upper portion of the light-emitting element 120, the image quality degradation caused by the scattering layer SL did not occur.

The embodiments of the present disclosure can be described as follows:

According to one or more embodiments of the present disclosure, there is provided a display device. The display device comprises a substrate on which a plurality of subpixels is defined, a plurality of light-emitting elements disposed on the substrate in each of the plurality of subpixels, a plurality of bonding layers disposed between the plurality of light-emitting elements and the substrate and configured to overlap the plurality of light-emitting elements, and a scattering layer disposed on the same plane as the plurality of bonding layers and configured to surround the plurality of bonding layers.

The plurality of bonding layers may completely overlap the plurality of light-emitting elements, respectively.

An area of a top surface of each of the plurality of bonding layers may be equal to an area of a bottom surface of each of the plurality of light-emitting elements respectively overlapping the plurality of bonding layers.

The plurality of scattering layers may be disposed outside the plurality of light-emitting elements.

An area of a top surface of each of the plurality of bonding layers may be larger than an area of a bottom surface of each of the plurality of light-emitting elements respectively overlapping the plurality of bonding layers.

The scattering layer may comprise scattering particles.

The scattering layer may further comprise a bonding material in which the scattering particles are dispersed.

The bonding material may be made of the same material as the plurality of bonding layers.

The display device may further comprise a driving transistor disposed on the substrate, a first planarization layer disposed on the driving transistor, a reflective electrode disposed on the first planarization layer, the plurality of bonding layer or the scattering layer disposed on the reflective layer, a second planarization layer at least partially disposed on the plurality of bonding layer or the scattering layer and configured to adjoin at least a part of a side surface of the light-emitting element, a third planarization layer disposed on the second planarization layer and configured to cover the light-emitting element, and a fourth planarization layer disposed on the third planarization layer.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
a plurality of subpixels on the substrate;
a plurality of light-emitting elements in each of the plurality of subpixels;
a plurality of bonding layers between the plurality of light-emitting elements and the substrate, the plurality of bonding layers overlapping the plurality of light-emitting elements; and
a scattering layer on a same plane as the plurality of bonding layers, the scattering layer surrounding the plurality of bonding layers.

2. The display device of claim 1, wherein the plurality of bonding layers completely overlaps the plurality of light-emitting elements.

3. The display device of claim 1, wherein a size of a top surface of each of the plurality of bonding layers is equal to a size of a bottom surface of each of the plurality of light-emitting elements, the plurality of light-emitting elements overlapping the plurality of bonding layers.

4. The display device of claim 1, wherein the scattering layer is non-overlapping with the plurality of light-emitting elements.

5. The display device of claim 1, wherein a size of a top surface of each of the plurality of bonding layers is larger than a size of a bottom surface of each of the plurality of light-emitting elements, the plurality of light-emitting elements overlapping the plurality of bonding layers.

6. The display device of claim 1, wherein the scattering layer comprises a plurality of scattering particles.

7. The display device of claim 6, wherein the scattering layer further comprises a bonding material in which the plurality of scattering particles are dispersed.

8. The display device of claim 7, wherein the bonding material includes a same material as the plurality of bonding layers.

9. The display device of claim 1, further comprising:
a driving transistor on the substrate;
a first planarization layer on the driving transistor;
a reflective electrode on the first planarization layer;
the plurality of bonding layers or the scattering layer on the reflective electrode;
a second planarization layer at least partially on the plurality of bonding layers or the scattering layer, the second planarization layer adjoining at least a part of a side surface of a light-emitting element of the plurality of light-emitting elements;
a third planarization layer on the second planarization layer, the third planarization layer covering the light-emitting element; and
a fourth planarization layer on the third planarization layer.
